(19) United States
(12) Patent Application Publication
(10) Pub. No.: US 2024/0255679 A1
(43) Pub. Date: Aug. 1, 2024

(54) METHOD OF MANUFACTURING SILICON OPTICAL MEMBER, SILICON OPTICAL MEMBER, AND LIGHT-EMITTING DEVICE

(71) Applicant: NICHIA CORPORATION, Anan-shi (JP)

(72) Inventor: Hiroaki YUTO, Awa-shi (JP)

(21) Appl. No.: 18/419,139

(22) Filed: Jan. 22, 2024

(30) Foreign Application Priority Data
Jan. 26, 2023 (JP) 2023-010287

(51) Int. Cl. G02B 5/08; G02B 1/02; G02B 1/10; H01S 5/00

(52) U.S. Cl. CPC G02B 5/0808; G02B 1/02; G02B 1/10; H01S 5/0071

(57) ABSTRACT

A method of manufacturing a silicon optical member includes: providing a silicon substrate having a first primary surface and a second primary surface; forming a mask pattern on the first primary surface; forming one or more inclined surfaces by wet etching the silicon substrate from the first primary surface using the mask pattern as a mask; forming a third primary surface at a location closer to the first primary surface than to the second primary surface by partially removing the silicon substrate from the second primary surface toward the first primary surface without reaching the one or more inclined surfaces while the silicon substrate is supported at the first primary surface; and singulating the silicon substrate into a plurality of silicon optical members such that each of the plurality of silicon optical members includes the third primary surface and at least one of the one or more inclined surfaces.

### CROSS-REFERENCE TO RELATED APPLICATION

This application claims priority to Japanese Patent Application No. 2023-010287 filed on Jan. 26, 2023, the disclosure of which is hereby incorporated herein by reference in its entirety.

### BACKGROUND

The present invention relates to a method of manufacturing silicon optical member, a silicon optical member, and a light-emitting device including a silicon optical member.

Japanese Patent Application Publication No. 2005-340408 A discloses a method of manufacturing mirrors from a silicon substrate, in which a mask is formed on the silicon substrate, a reflective base surface is formed by etching, the silicon substrate is bonded to a dummy substrate, the silicon substrate is polished from a side opposite to the reflective base surface, and the mirrors are singulated.

### SUMMARY

When a light-emitting device including a light-emitting element and optical members, such as a mirror, is manufactured, a small-sized optical member is sometimes demanded. When the size of the optical member is reduced, there can be advantages such as being able to reduce the size of the light-emitting device or to dispose a greater number of optical members in a light-emitting device having the same size.

In order to obtain a small-sized optical member from a silicon substrate, using a technology disclosed in Japanese Patent Application Publication No. 2005-340408 A alone is insufficient, and there are other technical matters that are to be considered. One object of the present invention is to achieve a small-sized silicon optical member.

A method of manufacturing a silicon optical member according to one embodiment includes: providing a silicon substrate having a first primary surface and a second primary surface opposite to the first primary surface; forming a mask pattern on the first primary surface; forming one or more inclined surfaces by wet etching the silicon substrate from the first primary surface using the mask pattern as a mask; forming a third primary surface at a location closer to the first primary surface than to the second primary surface by partially removing the silicon substrate from the second primary surface toward the first primary surface without reaching the one or more inclined surfaces while the silicon substrate is supported at the first primary surface; and singulating the silicon substrate into a plurality of silicon optical members such that each of the plurality of silicon optical members includes the third primary surface and at least one of the one or more inclined surfaces.

A silicon optical member according to one embodiment includes a silicon member including a lower surface, a first lateral surface meeting the lower surface and extending upward from the lower surface, a primary surface meeting the first lateral surface and extending obliquely upward from the first lateral surface at an angle of 45 degrees relative to the lower surface, a second lateral surface meeting the primary surface at a position opposite to the first lateral surface and extending downward from the primary surface, and a third lateral surface meeting the second lateral surface and extending downward from the second lateral surface at an angle of 90 degrees relative to the lower surface. A width between a side of the first lateral surface meeting the lower surface and a side of the first lateral surface meeting the primary surface is in a range of 30 μm to 100 μm, and a width between a lower end of the primary surface and an upper end of the primary surface is greater than a width between an end point of the lower surface at a first lateral surface side and an end point of the lower surface at a third lateral surface side.

A light-emitting device according to one embodiment includes a substrate including a mounting surface; the silicon optical member described above bonded to the mounting surface; an adjustment member having a first surface and a second surface opposite to the first surface, the second surface being bonded to the mounting surface, the adjustment member having a thickness in a range of 50 μm to 150 μm in a direction perpendicular to the mounting surface; and a semiconductor laser element bonded to the first surface of the adjustment member with a light-emitting surface facing the primary surface of the silicon optical member. A shortest distance from the semiconductor laser element to the silicon optical member in a direction parallel to the mounting surface is more than 0 μm and equal to or less than 100 μm.

Certain embodiments of the present invention can contribute to the achievement of a smaller-sized silicon optical member.

### BRIEF DESCRIPTION OF DRAWINGS

FIG. 1 is a plan view of a silicon optical member according to an embodiment.

FIG. 2A is a perspective view of a silicon optical member according to an embodiment as seen along a direction toward a reflective surface.

FIG. 2B is a perspective view of a silicon optical member according to an embodiment as seen along a direction toward a third lateral surface.

FIG. 3A is a schematic view for illustrating a step in a method of manufacturing a silicon optical member according to an embodiment.

FIG. 3B is a schematic view for illustrating another step in a method of manufacturing a silicon optical member according to an embodiment.

FIG. 3C is a schematic view for illustrating another step in a method of manufacturing a silicon optical member according to an embodiment.

FIG. 3D is a schematic view for illustrating another step in a method of manufacturing a silicon optical member according to an embodiment.

FIG. 3E is a schematic view for illustrating another step in a method of manufacturing a silicon optical member according to an embodiment.

FIG. 3F is a schematic view for illustrating another step in a method of manufacturing a silicon optical member according to an embodiment.

FIG. 3G is a schematic view for illustrating another step in a method of manufacturing a silicon optical member according to an embodiment.

FIG. 3H is a schematic view for illustrating another step in a method of manufacturing a silicon optical member according to an embodiment.

FIG. 4A is an image illustrating two examples of silicon optical members according to an embodiment and a comparative example of a silicon optical member.

FIG. 4B is an image illustrating a first example of two examples of silicon optical members according to an embodiment.

FIG. 4C is an image illustrating a second example of two examples of silicon optical members according to an embodiment.

FIG. 5 is a perspective view of a light-emitting device according to an embodiment.

FIG. 6 is a perspective view of a light-emitting device according to an embodiment, in a state in which a cover of a package is removed.

FIG. 7 is a top view of the light-emitting device in a state illustrated in FIG. 6.

FIG. 8 is a cross-sectional view taken along a section line VIII-VIII in FIG. 5.

### DETAILED DESCRIPTION

In the present description or the claims, polygons such as triangles and quadrangles include polygonal shapes in which the corners of the polygon are modified, for example, rounded, beveled, chamfered, or coved. Not only shapes with such modification at corners (ends of sides) but also shapes with modification at an intermediate portion of a side are similarly referred to as a polygon. That is, a polygon-based shape with partial modification is included in the interpretation of “polygon” described in the present description and the claims.

The same applies not only to polygons but also to words representing specific shapes such as trapezoids, circles, protrusions, and recesses. The same applies when dealing with each side included in that shape. That is, even if a corner or an intermediate portion of a certain side is modified, the interpretation of “side” includes the modified portion. When a “polygon” or “side” without partial modification is to be distinguished from a processed shape, “exact” will be added to the description as in, for example, “exact quadrangle”.

Furthermore, in the present description or the claims, descriptions such as upper and lower, left and right, front and back, front and rear (frontward and rearward), near and far, and the like are used merely to describe the relative relationship of positions, orientations, directions, and the like, and the expressions need not match an actual relationship at the time of use.

In the drawings, directions such as an X direction, a Y direction, and a Z direction may be indicated by using arrows. The directions of the arrows are consistent across multiple drawings of the same embodiment. In addition, in the drawings, the directions of the arrows marked with X, Y, and Z are the positive directions, and the directions opposite thereto are the negative directions. For example, the direction marked with X at the tip of the arrow is the X direction and the positive direction. The direction, which is the X direction and is the positive direction, will be referred to as the “positive X direction ” and the direction opposite to this will be referred to as the “negative X direction”. The same applies to the Y direction and Z direction.

The term “member” or “portion” may be used to describe a component or the like in the present description. The term “member” refers to an object treated as a physically single member. The object treated as a physically single member can be an object treated as one part in a manufacturing step. On the other hand, the term “portion” refers to an object that need not be treated as a physically single member. For example, the term “portion” is used when part of one member is partially considered, a plurality of members are collectively considered as one object, or the like.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present invention.

In the present description and the claims, when a plurality of components are present and these components are to be indicated separately, the components may be distinguished by adding the terms “first” and “second” at the beginning of the names of the components. Objects to be distinguished may differ between the present description and the claims. Thus, even when a component in the claims is given the same term as that in the present description, the object identified by that component is not the same across the present description and the claims in some cases.

For example, when components distinguished by being termed “first”, “second”, and “third” are present in the present description, and when components given the terms “first” and “third” in the present description are described in the claims, these components may be distinguished by being denoted as “first” and “second” in the claims for ease of understanding. In this case, the components denoted as “first” and “second” in the claims refer to the components termed “first” and “third” in the present description, respectively. This rule applies to not only components but also other objects in a reasonable and flexible manner.

Embodiments for implementing the present invention will be described below. Specific embodiments for implementing the present invention will be described below with reference to the drawings. Embodiments for implementing the present invention are not limited to the specific embodiments to be described below. That is, the embodiments illustrated in the drawings are not the only form in which the present invention is achieved. Sizes, positional relationships, and the like of members illustrated in each of the drawings may sometimes be exaggerated in order to facilitate understanding.

### Embodiment

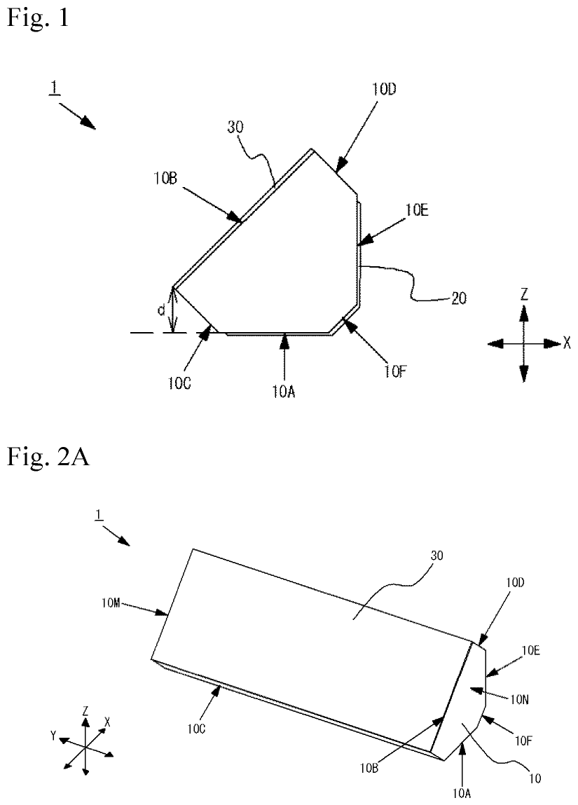

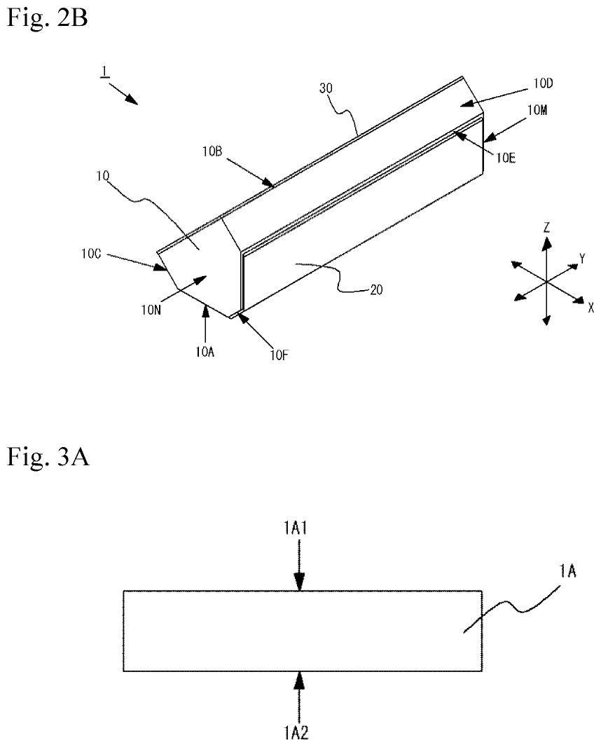

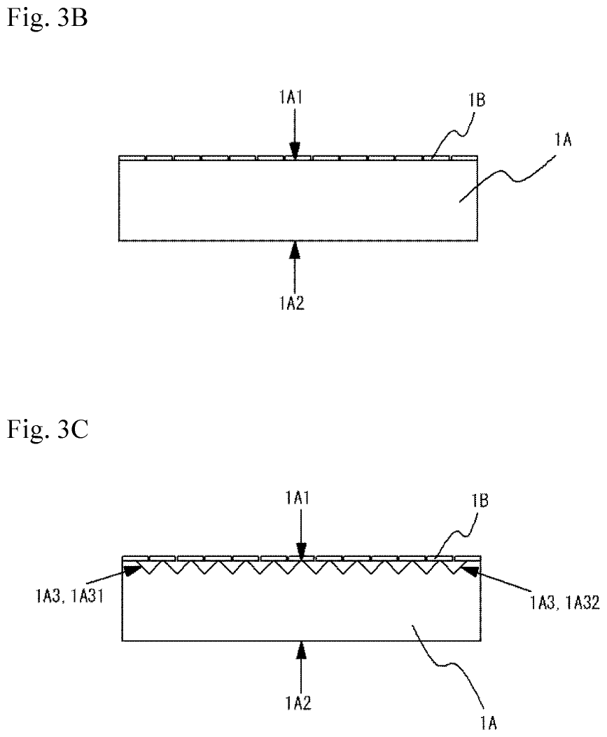

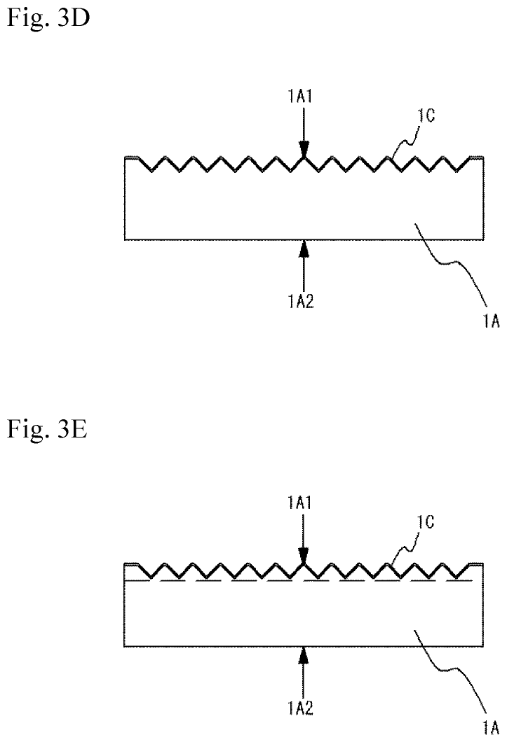

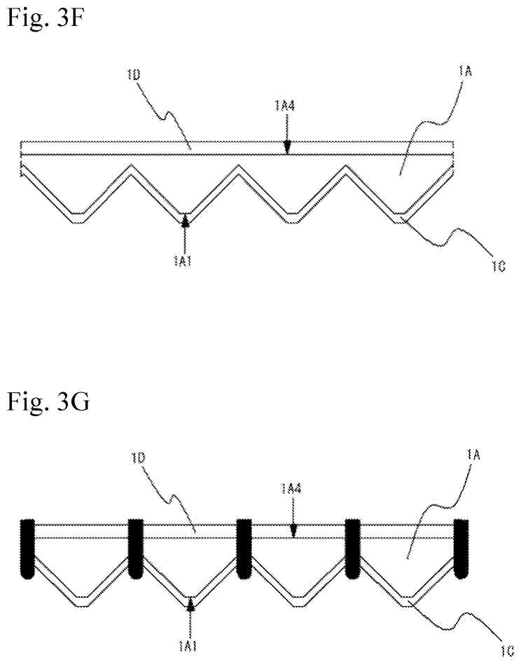

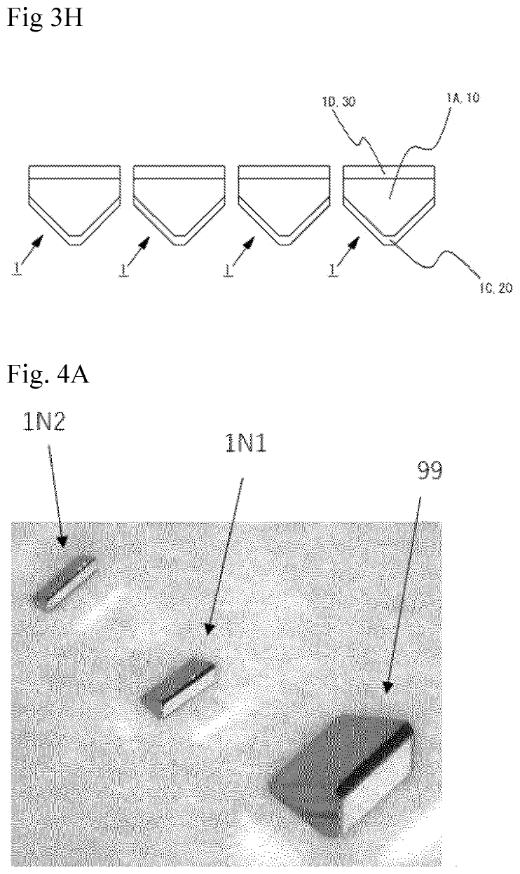

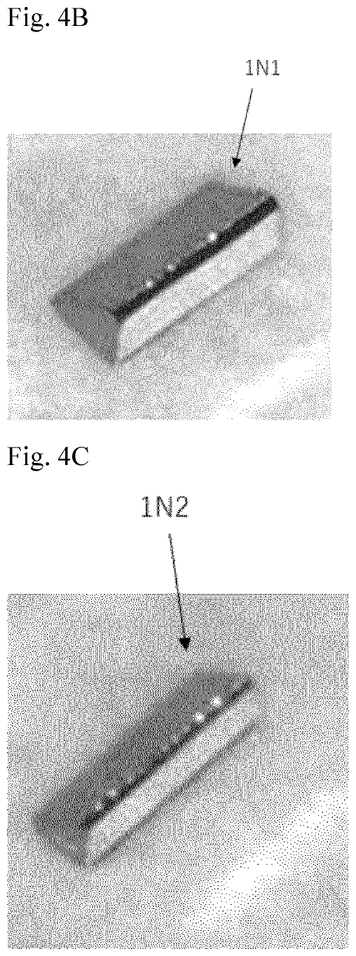

A silicon optical member 1 according to one embodiment will be described. FIGS. 1, 2A, 2B, 3A to 3H, and 4A to 4C are drawings for illustrating an exemplary form of the silicon optical member 1. FIG. 1 is a schematic plan view of the silicon optical member 1. FIG. 2A is a schematic perspective view of the silicon optical member 1 as seen along a direction toward a reflective surface. FIG. 2B is a schematic perspective view of the silicon optical member 1 as seen along a direction toward a third lateral surface 10E. FIGS. 3A to 3H are schematic views for illustrating a method of manufacturing the silicon optical member 1. The broken line drawn in FIG. 3E indicates a line on which a third primary surface is formed in a silicon substrate 1A. Furthermore, FIGS. 3F to 3H are illustrated in an enlarged manner compared with FIGS. 3A to 3E. FIG. 4A is an image illustrating respective examples of the silicon optical member 1 and a comparative example of a silicon optical member. FIG. 4B is an image illustrating a first example of the silicon optical member 1. FIG. 4C is an image illustrating a second example of the silicon optical member 1.

The silicon optical member 1 includes one or more components. The one or more components include a silicon member 10. The one or more components further include a metal film 20 and a reflective film 30. The silicon optical member 1 mayinclude a component other than the components described above. In addition, the silicon optical member 1 need not include all of the components of the silicon optical member 1 described in the present description.

First, each of the components will be described.

### Silicon Member 10

The main material of the silicon member 10 is silicon. The silicon member 10 is made of silicon.

The term “main material” as used herein refers to a material that occupies the greatest proportion of a target formed product in terms of mass or volume. When a target formed product is formed of a single material, that material is the main material. In other words, when a certain material is the main material, the proportion of that material may be 100%.

The silicon member 10 has a lower surface 10A, a primary surface 10B, a first lateral surface 10C, a second lateral surface 10D, and a third lateral surface 10E. Furthermore, the silicon member 10 further includes a fourth lateral surface 10F. The primary surface 10B is inclined at an angle of 45 degrees relative to the lower surface 10A. The third lateral surface 10E is perpendicular to the lower surface 10A. The fourth lateral surface 10F is parallel to the primary surface 10B.

The first lateral surface 10C meets the lower surface 10A and extends upward from the lower surface 10A. The primary surface 10B meets the first lateral surface 10C and extends upward from the first lateral surface 10C. The primary surface 10B extends obliquely upward from the first lateral surface 10C at an angle of 45 degrees relative to the lower surface 10A.

The second lateral surface 10D meets the primary surface 10B and extends downward from the primary surface 10B. The second lateral surface 10D meets the primary surface 10B at a position opposite to the first lateral surface 10C. The third lateral surface 10E meets the second lateral surface 10D and extends downward from the second lateral surface 10D. The third lateral surface 10E extends downward from the second lateral surface 10D at an angle of 90 degrees relative to the lower surface 10A. The fourth lateral surface 10F meets the third lateral surface 10E and extends downward from the third lateral surface 10E. The fourth lateral surface 10F meets the lower surface 10A at a position opposite to the third lateral surface 10E.

The lower surface 10A has a first side and a second side opposite to the first side. Furthermore, the lower surface 10A has a third side and a fourth side opposite to the third side. The third side and the fourth side of the lower surface 10A are both connected to the first side and the second side of the lower surface 10A. An outer shape of the lower surface 10A is rectangular. The outer shape of the lower surface 10A need not be rectangular.

The primary surface 10B has an upper side and a lower side. The primary surface 10B also has two lateral sides. An outer shape of the primary surface 10B is rectangular. The two lateral sides of the primary surface 10B are both connected to the upper side and the lower side of the primary surface 10B. The outer shape of the primary surface 10B need not be rectangular.

The third lateral surface 10E has an upper side and a lower side. The third lateral surface 10E also has two lateral sides. An outer shape of the third lateral surface 10E is rectangular. The two lateral sides of the third lateral surface 10E are both connected to the upper side and the lower side of the third lateral surface 10E. The outer shape of the third lateral surface 10E need not be rectangular.

The first lateral surface 10C and the primary surface 10B share a side (the lower side of the primary surface 10B), and the first lateral surface 10C and the lower surface 10A share a side (the first side of the lower surface 10A). In other words, the lower side of the primary surface 10B can be referred to as a side of the first lateral surface 10C that meets the primary surface 10B, and the first side of the lower surface 10A can be referred to as a side of the first lateral surface 10C that meets the lower surface 10A. An outer shape of the first lateral surface 10C is rectangular. The outer shape of the first lateral surface 10C need not be rectangular.

The second lateral surface 10D and the primary surface 10B share a side (the upper side of the primary surface 10B), and the second lateral surface 10D and the third lateral surface 10E share a side (the upper side of the third lateral surface 10E). An outer shape of the second lateral surface 10D is rectangular. The outer shape of the second lateral surface 10D need not be rectangular. The fourth lateral surface 10F and the lower surface 10A share a side (the second side of the lower surface 10A), and the fourth lateral surface 10F and the third lateral surface 10E share a side (the lower side of the third lateral surface 10E). An outer shape of the fourth lateral surface 10F is rectangular. The outer shape of the fourth lateral surface 10F need not be rectangular.

A width between a side of the first lateral surface 10C meeting the lower surface 10A and a side of the first lateral surface 10C meeting the primary surface 10B is in a range of 30 μm to 100 μm. Furthermore, this width is preferably less than 60 μm. The smaller this width is, the shorter the distance from the lower surface 10A to the lower side of the primary surface 10B is, and thus, the primary surface 10B can be closer to the lower surface 10A.

A width between a side of the second lateral surface 10D meeting the third lateral surface 10E and a side of the second lateral surface 10D meeting the primary surface 10B is in a range of 30 μm to 100 μm. Furthermore, this width is preferably the same as the width between the side of the first lateral surface 10C meeting the lower surface 10A and the side of the first lateral surface 10C meeting the primary surface 10B.

A width between a side of the fourth lateral surface 10F meeting the lower surface 10A and a side of the fourth lateral surface 10F meeting the third lateral surface 10E is in a range of 5 μm to 45 μm. Furthermore, this width is equal to or less than one fourth of a width between the first side of the lower surface 10A and the second side of the lower surface 10A. This width is preferably equal to or less than one sixth of the width between the first side of the lower surface 10A and the second side of the lower surface 10A. The smaller this width is, the greater the width between the first side of the lower surface 10A and the second side of the lower surface 10A can be secured, and the bonding of the silicon optical member 1 can be more stabilized.

When the shortest distance from the lower surface 10A to the primary surface 10B (distance from the first side of the lower surface 10A to the lower side of the primary surface 10B) is divided into a directional component perpendicular to the lower surface 10A and a directional component parallel to the lower surface 10A, a distance of the directional component perpendicular to the lower surface 10A (distance d in FIG. 1) is in a range of 10 μm to 50 μm.

In addition, the silicon member 10 has a fifth lateral surface 10M that shares the third side of the lower surface 10A with the lower surface 10A, one of the two lateral sides of the primary surface 10B with the primary surface 10B, and one of the two lateral sides of the third lateral surface 10E with the third lateral surface 10E. The silicon member 10 also has a sixth lateral surface 10N that shares the fourth side of the lower surface 10A with the lower surface 10A, the other of the two lateral sides of the primary surface 10B with the primary surface 10B, and the other of the two lateral sides of the third lateral surface 10E with the third lateral surface 10E.

Outer shapes of the fifth lateral surface 10M and the sixth lateral surface 10N are not rectangular. The outer shapes of the fifth lateral surface 10M and the sixth lateral surface 10N are hexagonal. This hexagon has a shape obtained by cutting off three corners of a triangle. The outer shapes of the fifth lateral surface 10M and the sixth lateral surface 10N are not an exact triangle.

The primary surface 10B of the silicon member 10 is made of a {110} plane. As used herein, the {110} plane refers to planes including the (110) plane, which is one of crystal lattice planes in a diamond structure being a crystal structure of silicon that is stable at normal temperature and normal pressure, and all equivalent crystal planes thereof. The equivalent crystal plane means a family of equivalent crystal planes or facets defined by Miller indices.

The fourth lateral surface 10F of the silicon member 10 is made of the {110} plane. The primary surface 10B and the fourth lateral surface 10F are parallel to each other. The primary surface 10B and the fourth lateral surface 10F may be at an off-angle within ±2 degrees relative to the {110} plane. This off-angle is preferably within ±1 degrees, and more preferably within ±0.2 degrees.

The lower surface 10A of the silicon member 10 is made of a {100} plane. The third lateral surface 10E of the silicon member 10 is made of the {100} plane. An angle formed by the lower surface 10A and the fourth lateral surface 10F is 135 degrees. An angle formed by the third lateral surface 10E and the fourth lateral surface 10F is 135 degrees. The lower surface 10A and the third lateral surface 10E may be at an off-angle within ±2 degrees relative to the {100} plane. This off-angle is preferably within ±1 degrees, and more preferably within ±0.2 degrees.

An area of the primary surface 10B of the silicon member 10 is larger than an area of the lower surface 10A. The area of the primary surface 10B of the silicon member 10 is larger than an area of the third lateral surface 10E. The area of the primary surface 10B of the silicon member 10 is larger than an area of the fourth lateral surface 10F. The lower surface 10A and the third lateral surface 10E of the silicon member 10 have the same shape and area. The term “same shape” used herein includes a case in which a difference in dimension ratio between the vertical and horizontal directions is within 200%, and the term “same area” used herein includes a case in which the larger area is within 200% of the smaller area.

The silicon member 10 illustrated by the drawings has a width in the X direction in a range of 100 μm to 550 μm. A width in the Y direction is in a range of 300 μm to 1000 μm. A width in the Z direction is in a range of 100 μm to 550 μm. Lengths of the first side and the second side of the lower surface 10A are in a range of 300 μm to 1000 μm. Lengths of the third side and the fourth side of the lower surface 10A are in a range of 100 μm to 550 μm. A distance from an upper end to a lower end of the primary surface 10B is in a range of 150 μm to 750 μm. A distance from the primary surface 10B to the fourth lateral surface 10F is in a range of 100 μm to 400 μm.

In the silicon member 10, the width between the lower end and the upper end of the primary surface 10B is greater than a width between an end point of the lower surface 10A at a first lateral surface 10C side and an end point of the lower surface 10A at a third lateral surface 10E side. In the silicon member 10 illustrated in the drawings, an end point of the lower surface 10A at the first lateral surface 10C side is located on the first side of the lower surface 10A, and an end point of the lower surface 10A at the third lateral surface 10E side is located on the second side of the lower surface 10A. The lower end of the primary surface 10B is located on the lower side of the primary surface 10B, and the upper end of the primary surface 10B is located on the upper side of the primary surface 10B.

The longest distance in the X direction from the lower end of the primary surface 10B to the third lateral surface 10E can be the width of the silicon member 10 in the X direction. The longest distance in the Y direction from the fifth lateral surface 10M to the sixth lateral surface 10N can be the width of the silicon member 10 in the Y direction. The longest distance (height) in the Z direction from the lower surface 10A to the upper end of the primary surface 10B can be the width of the silicon member 10 in the Z direction.

The primary surface 10B of the silicon member 10 has a width in the Y direction that is greater than the width between the lower end and the upper end of the primary surface 10B. The width in the Y direction is in a range of 1.5 times to 3 times the width between the lower end and the upper end of the primary surface 10B. The silicon member 10 mayhave a width in the Y direction that is smaller than the width between the lower end and the upper end of the primary surface 10B.

### Metal Film 20

For the metal film 20, a metal material can be used as a main material. As the main material of the metal film 20, for example, a single-component metal, such as Cu, Ag, Al, Ni, Ru, Rh, Au, Ti, Pt, Pd, Mo, Cr, and W, or an alloy containing any of these metals can be used. In one example, the metal film 20 can be made of Ti/Ru/Au.

The metal film 20 is provided on the lower surface 10A of the silicon member 10. Furthermore, the metal film 20 is provided on the third lateral surface 10E of the silicon member 10. Furthermore, the metal film 20 is provided on the fourth lateral surface 10F of the silicon member 10.

An outer edge of the metal film 20 provided on the lower surface 10A is spaced apart from the first side of the lower surface 10A. That is, the outer edge of the metal film 20 provided on the lower surface 10A is located inward of the first side of the lower surface 10A. The outer edge of the metal film 20 provided on the lower surface 10A overlaps with the second side of the lower surface 10A. That is, the outer edge of the metal film 20 provided on the lower surface 10A is located on the second side of the lower surface 10A.

The outer edge of the metal film 20 provided on the lower surface 10A is spaced apart from the third side and the fourth side of the lower surface 10A. In other words, the outer edge of the metal film 20 provided on the lower surface 10A is located inward of the third side of the lower surface 10A and also inward of the fourth side of the lower surface 10A.

An outer edge of the metal film 20 provided on the third lateral surface 10E is spaced apart from the upper side of the third lateral surface 10E. That is, the outer edge of the metal film 20 provided on the third lateral surface 10E is located inward of the upper side of the third lateral surface 10E. The outer edge of the metal film 20 provided on the third lateral surface 10E overlaps with the lower side of the third lateral surface 10E. That is, the outer edge of the metal film 20 provided on the third lateral surface 10E is located on the lower side of the third lateral surface 10E.

The outer edge of the metal film 20 provided on the third lateral surface 10E is spaced apart from the two lateral sides of the third lateral surface 10E. That is, the outer edge of the metal film 20 provided on the third lateral surface 10E is located inward of one lateral side of the two lateral sides of the third lateral surface 10E and also inward of the other lateral side of the two lateral sides of the third lateral surface 10E.

An outer edge of the metal film 20 provided on the fourth lateral surface 10F overlaps with the side of the fourth lateral surface 10F shared with the second side of the lower surface 10A. In other words, the outer edge of the metal film 20 provided on the fourth lateral surface 10F is located on this side of the fourth lateral surface 10F. The outer edge of the metal film 20 provided on the fourth lateral surface 10F overlaps with the side of the fourth lateral surface 10F shared with the lower side of the third lateral surface 10E. In other words, the outer edge of the metal film 20 provided on the fourth lateral surface 10F is located on this side of the fourth lateral surface 10F.

The outer edge of the metal film 20 provided on the fourth lateral surface 10F is spaced apart from a lateral side of the fourth lateral surface 10F shared with the fifth lateral surface 10M and a lateral side of the fourth lateral surface 10F shared with the sixth lateral surface 10N. That is, the outer edge of the metal film 20 provided on the fourth lateral surface 10F is located inward of one lateral side of the two lateral sides of the fourth lateral surface 10F and also inward of the other lateral side of the two lateral sides of the fourth lateral surface 10F.

Reflective Film 30 The reflective film 30 can be formed using a dielectric multilayer film as the main material. The reflective film 30 can be formed using, for example, a dielectric multilayer film such as Ta₂O₅/SiO₂, TiO/SiO₂, and Nb₂O₅/SiO₂. The reflective film 30 maybe formed using metal as the main material. For example, the reflective film 30 can be formed using a metal, such as Ag or Al.

The reflective film 30 is provided on the primary surface 10B of the silicon member 10. The reflective film 30 is substantially provided on the entire primary surface 10B.

A distance from the lower side of the primary surface 10B to an outer edge of the reflective film 30 provided on the primary surface 10B is smaller than a distance from the first side of the lower surface 10A to an outer edge of the metal film 20 provided on the lower surface 10A.

A distance from the upper side of the primary surface 10B to an outer edge of the reflective film 30 provided on the primary surface 10B is smaller than a distance from the upper side of the third lateral surface 10E to an outer edge of the metal film 20 provided on the third lateral surface 10E.

A distance from one lateral side of the two lateral sides of the primary surface 10B to the outer edge of the reflective film 30 provided on the primary surface 10B is smaller than a distance from the third side of the lower surface 10A to an outer edge of the metal film 20 provided on the lower surface 10A and also smaller than a distance from the fourth side of the lower surface 10A to an outer edge of the metal film 20 provided on the lower surface 10A. A distance from the other lateral side of the two lateral sides of the primary surface 10B to an outer edge of the reflective film 30 provided on the primary surface 10B is also smaller than the distance from the third side of the lower surface 10A to an outer edge of the metal film 20 provided on the lower surface 10A and also smaller than the distance from the fourth side of the lower surface 10A to an outer edge of the metal film 20 provided on the lower surface 10A.

### Manufacturing Method of Silicon Optical Member 1

Subsequently, the method of manufacturing the silicon optical member 1 will be described. The silicon optical member 1 can be manufactured by a manufacturing method including a step of providing a silicon substrate 1A having a first primary surface 1A1 and a second primary surface 1A2; a step of forming a mask pattern 1B on the silicon substrate 1A; a step of forming an inclined surface 1A3 on the silicon substrate 1A; a step of forming a metal film 1C on the silicon substrate 1A; a step of forming a third primary surface 1A4 on the silicon substrate 1A; a step of providing a reflective film 1D on the third primary surface 1A4 of the silicon substrate 1A; and a step of singulating the silicon substrate 1A into a plurality of silicon optical members.

In the step of providing the silicon substrate 1A, the silicon substrate 1A having the first primary surface 1A1 and the second primary surface 1A2 is provided. The second primary surface 1A2 is a surface opposite to the first primary surface 1A1. The first primary surface 1A1 is made of the {110} plane of silicon. The second primary surface 1A2 is made of the {110} plane of silicon. The main material of the silicon substrate 1A is silicon. The silicon substrate 1A is made of silicon.

A thickness of the silicon substrate 1A between the first primary surface 1A1 and the second primary surface 1A2 is, for example, in a range of 500 μm to 1000 μm. The thickness of the silicon substrate 1A between the first primary surface 1A1 and the second primary surface 1A2 is preferably in a range of 200% to 600% of the thickness in the same direction of the silicon optical member 1 to be manufactured. Accordingly, it is possible to reduce the occurrence of defects, such as unintended cracking of the silicon substrate 1A during the process.

In the step of forming the mask pattern 1B on the silicon substrate 1A, the mask pattern 1B is formed on the first primary surface 1A1 of the silicon substrate 1A. The mask pattern 1B has, for example, openings extending in a <100> direction. The openings extending in the <100> direction can be openings extending in a direction parallel to the first primary surface 1A1.

The term “<100> direction” used herein refers to directions including a direction perpendicular to a (100) plane, which is one of crystal lattice planes in a diamond structure being a crystal structure of silicon that is stable at normal temperature and normal pressure, and all directions perpendicular to an equivalent crystal plane thereof.

The openings of the mask pattern 1B may have a stripe shape extending in the <100> direction. Alternatively, they may have a lattice shape connected to openings extending in the direction perpendicular to the <100> direction (that is, a <110> direction). For example, they may have a lattice shape connected to openings extending in the <110> direction. In addition, it is preferable that outer edges (both ends) of the openings extending in the <100> direction are substantially parallel to the <100> direction, and it is preferable that outer edges (both ends) of the openings extending in the <110> direction are substantially parallel to the <110> direction.

The mask pattern 1B can be formed by a known method using a known material, such as a resist film or an insulating film (such as an oxide film or a nitride film of Si, Hf, Zr, Al, Ti, or La, or a composite film thereof). It is preferable that the material of the mask pattern 1B is appropriately selected depending on the type of an etchant for wet etching described below.

In the step of forming the inclined surface 1A3 on the silicon substrate 1A, the mask pattern 1B is used as a mask to etch the silicon substrate 1A from the first primary surface 1A1, thereby forming one or more the inclined surfaces 1A3. For example, the inclined surface 1A3 can be formed by wet etching the silicon substrate 1A from the first primary surface 1A1. By performing this step, the inclined surface 1A3 inclined from the first primary surface 1A1 is formed.

By performing this step, a plurality of the inclined surfaces 1A3 are formed on the silicon substrate 1A. The plurality of inclined surfaces 1A3 include a first inclined surface 1A31 and a second inclined surface 1A32 located opposite to each other. In the silicon substrate 1A, a plurality of the first inclined surfaces 1A31 and a plurality of the second inclined surfaces 1A32, each first inclined surface 1A31 and a respective second inclined surface 1A32 facing each other, can be formed. For example, ten or more first inclined surfaces 1A31 and ten or more second inclined surfaces 1A32, each first inclined surface 1A31 and a respective second inclined surface 1A32 facing each other, can be formed in one silicon substrate 1A.

A length, in a direction perpendicular to the first primary surface 1A1, of the inclined surface 1A3 formed by this step is in a range of 100 μm to 300 μm. A length of the inclined surface 1A3 in the direction parallel to the first primary surface 1A1 is in a range of 100 μm to 300 μm.

In the silicon substrate 1A on which the inclined surface 1A3 is formed, it is preferable that 150% or more of a width between the first primary surface 1A1 and a point of the inclined surface 1A3 farthest from the first primary surface 1A1 in the direction perpendicular to the first primary surface 1A1 is secured as a width between this point and the second primary surface 1A2 in the direction perpendicular to the first primary surface 1A1. Alternatively, the width between this point and the second primary surface 1A2 in the direction perpendicular to the first primary surface 1A1 is preferably in a range of 250% to 750% of the width between the first primary surface 1A1 and this point. When being 200% or more, it is possible to suppress the occurrence of defects, such as unintended cracking of the silicon substrate 1A. When being 750% or less, it is possible to avoid an excessive workload being applied to the subsequent step of forming a reflective base surface.

In a plan view as seen along the direction perpendicular to the first primary surface 1A1 (hereinafter referred to as a top view), the first inclined surface 1A31 and the second inclined surface 1A32 are each made of a plane extending in a direction (hereinafter referred to as a second direction) perpendicular to a direction (hereinafter referred to as a first direction) in which the first inclined surface 1A31 and the second inclined surface 1A32 face each other.

In this step, a connection region having a width in the first direction is formed between the first inclined surface 1A31 and the second inclined surface 1A32 located opposite to each other. A width of the connection region to be formed is, for example, 500 μm or less. The connection region is a region connecting the first inclined surface 1A31 and the second inclined surface 1A32 facing each other. In a case in which a lower end of the first inclined surface 1A31 and a lower end of the second inclined surface 1A32 are connected to each other, this connected portion is the connection region. In other words, the connection region need not have a width in the first direction, and the boundary line at which the first inclined surface 1A31 and the second inclined surface 1A32 are connected can also be regarded as the connection region.

It can be said that a plurality of grooves including the two inclined surfaces 1A3 (the first inclined surface 1A31 and the second inclined surface 1A32) facing each other and the connection region are formed in the silicon substrate 1A by this step. In addition, a structure in which the groove is formed between two first primary surfaces 1A1 is formed. The two first primary surfaces 1A1 between which the groove is formed may be connected to each other. Examples of such a structure includes a structure in which the first primary surfaces 1A1 surround the groove. An interval between the first primary surfaces 1A1 adjacent to each other across the groove is in a range of 200 μm to 500 μm.

The inclined surface 1A3 includes the {100} plane of silicon. The first inclined surface 1A31 and the second inclined surface 1A32 each include the {100} plane of silicon. The inclined surface 1A3 extends in the <100> direction and is at an inclination angle of 45 degrees relative to the second primary surface 1A2 of the silicon substrate 1A (that is, the {110} plane). The inclined surface 1A3 may be an off-angle of about ±2 degrees relative to the {100} plane.

In the step of forming the metal film 1C on the silicon substrate 1A, the metal film 1C is formed on the inclined surface 1A3. The metal film 1C is formed on the first inclined surface 1A31 and the second inclined surface 1A32 facing each other. In this step, the metal film 1C is formed from the first inclined surface 1A31 to the second inclined surface 1A32. The metal film 1C is also formed on the connection region. For example, on the first primary surface 1A1 side of the silicon substrate 1A, the metal film 1C is formed in the entirety of a region enclosing all the inclined surfaces 1A3. The maximum thickness of the metal film 1C formed in this step can be in a range of 200 nm to 1000 nm.

As the metal film 1C, for example, one or more of single-component metals such as Cu, Ag, Al, Ni, Rh, Au, Ti, Pt, Pd, Mo, Cr, and W or an alloy containing these metals can be selected and be used. For example, the metal film 1C can be made of a metal layer of Ti/Ru/Au.

In the step of forming the third primary surface 1A4 on the silicon substrate 1A, the silicon substrate 1A is partially removed from the second primary surface 1A2 toward the first primary surface 1A1 of the silicon substrate 1A to form the third primary surface 1A4. The third primary surface 1A4 is formed closer to the first primary surface 1A1 than the second primary surface 1A2.

In this step, the silicon substrate 1A is partially removed such that the third primary surface 1A4 does not reach the one or more inclined surfaces 1A3. Therefore, the third primary surface 1A4 does not connect to the inclined surface 1A3. The third primary surface 1A4 reaching the inclined surface 1A3 would mean that a through hole is formed in the silicon substrate 1A. By removing the silicon substrate 1A such that the third primary surface 1A4 does not reach the inclined surfaces 1A3, the size of the silicon optical member 1 can be reduced. Moreover, treatment in a subsequent step of disposing the reflective film 1D is facilitated.

In the direction perpendicular to the first primary surface 1A1, a width of a portion between the second primary surface 1A2 and the third primary surface 1A4 of the silicon substrate 1A, the portion being to be removed in this step, is greater than a width of the inclined surface 1A3 formed in the step of forming the inclined surfaces 1A3 in the silicon substrate 1A. Thus, by securing a sufficient width for removal in the silicon substrate 1A, a small-sized silicon optical member can be stably manufactured.

The shortest distance from the third primary surface 1A4 to the inclined surface 1A3 is in a range of 5 μm to 60 μm. This shortest distance is preferably in a range of 10 μm to 50 μm. When the distance is 10 μm or more, there is an advantage that the through hole is not formed. When the distance is 50 μm or less, there is an advantage that the third primary surface 1A4 can be brought close to the inclined surface 1A3.

The partial removal of the silicon substrate 1A can be performed by, for example, polishing, grinding, or cutting. It can also be performed by chemical polishing, electrolytic polishing, mechanical polishing, or the like. It is also possible to employ a method of physical removal using a machine, such as mechanical polishing.

The partial removal of the silicon substrate 1A can be performed in a state in which a support base supports the first primary surface 1A1 of the silicon substrate 1A. By supporting the silicon substrate 1A, the operation in this step can be carried out in a stable state.

The third primary surface 1A4 functions as the reflective surface in the silicon optical member 1. For example, the third primary surface 1A4 itself may be used as the reflective surface, or the reflective film 1D may be provided on the third primary surface 1A4 in the step of disposing the reflective film 1D described below and used as the reflective surface in this state.

In the step of disposing the reflective film 1D on the silicon substrate 1A, the reflective film 1D is disposing on the third primary surface 1A4. The reflective film 1D can be formed on the third primary surface 1A4 to have a thickness, for example, in a range of 0.1 μm to 10 μm. The reflective film 1D can be made of a material adapted to reflect 50% or more of light from a semiconductor laser element 12.

The reflective film 1D can be made of a dielectric multilayer film formed of a plurality of layers in which two or more types of dielectrics are layered. The dielectric multilayer film is preferably a distributed Bragg reflector (DBR) film. Examples of the dielectrics constituting the DBR film include an oxide or a nitride containing at least one element selected from the group consisting of, for example, Si, Ti, Zr, Nb, Ta, and Al. The reflective film 1D can also be made of a metal, such as Al, Au, Ag, or Cr.

In the step of singulating the silicon substrate 1A into a plurality of the silicon optical members 1, the silicon substrate 1A is divided to be singulated into the plurality of silicon optical members 1. Each silicon optical member 1 includes the inclined surface 1A3 and the third primary surface 1A4. Also, each silicon optical member 1 includes the first inclined surface 1A31 and the second inclined surface 1A32. The first inclined surface 1A31 and the second inclined surface 1A32 of the silicon optical member 1 are not the first inclined surface 1A31 and the second inclined surface 1A32 that faced each other in the silicon substrate 1A prior to the step of singulating.

Singulation of the silicon substrate 1A into the plurality of silicon optical members 1 can be achieved by dicing, for example. The silicon substrate 1A is diced in a direction perpendicular to the groove formed between the two first primary surfaces 1A1 in a top view. Furthermore, the silicon substrate 1A is diced so as to pass through the connection region in a direction parallel to this groove in a top view (see FIG. 3G).

The respective silicon optical members 1 do not include the connection region. For example, when dicing is performed so as to pass through the connection region, a blade having a width greater than a width of the connection region (width in a direction parallel to an inclination direction in a top view) is used, so that the silicon substrate 1A can be singulated into silicon optical members 1 not including the connection region. When the inclined surface 1A3 is used as a mounting surface and bonded to other members, if the connection region remained, the mounting accuracy of the reflective surface might be adversely affected.

Dividing the silicon substrate 1A in this manner allows for manufacturing the plurality of silicon optical members 1. In the silicon substrate 1A at the time when the singulation step is performed, a width between the first primary surface 1A1 and the point of the first inclined surface 1A31 farthest from the first primary surface 1A1 in the direction perpendicular to the first primary surface 1A1 is greater than a width between this point and the third primary surface 1A4 in the direction perpendicular to the first primary surface 1A1.

Here, the correspondence between the silicon substrate 1A and the silicon optical member 1 will be described. The first primary surface 1A1 of the silicon substrate 1A corresponds to the fourth lateral surface 10F of the silicon member 10, the third primary surface 1A4 of the silicon substrate 1A corresponds to the primary surface 10B of the silicon member 10, and the first inclined surface 1A31 and the second inclined surface 1A32 of the silicon substrate 1A correspond to the lower surface 10A and the third lateral surface 10E of the silicon member 10. Furthermore, two cut surfaces obtained by cutting adjacent connection regions in the silicon substrate 1A correspond to the first lateral surface 10C and the second lateral surface 10D of the silicon member 10. The metal film 1C to be provided on the silicon substrate 1A corresponds to the metal film 20 to be provided on the silicon member 10, and the reflective film 1D to be provided on the silicon substrate 1A corresponds to the reflective film 30 to be provided on the silicon member 10.

### Silicon Optical Member 1 of First Example

An example of the silicon optical member 1 manufactured based on the above-described manufacturing method will be described. FIG. 4B is an image illustrating a silicon optical member 1N1 according to the first example. In the silicon optical member 1N1, the width between a side of the first lateral surface 10C meeting the lower surface 10A and a side of the first lateral surface 10C meeting the primary surface 10B is 50 μm. The width between a side of the second lateral surface 10D meeting the third lateral surface 10E and a side of the second lateral surface 10D meeting the primary surface 10B is 50 μm. The width between a side of the fourth lateral surface 10F meeting the lower surface 10A and a side of the fourth lateral surface 10F meeting the third lateral surface 10E is 30 μm. The distance d is 40 μm. The width of the silicon member 10 in the X direction is 310 μm. The width of the silicon member 10 in the Y direction is 650 μm. The width of the silicon member 10 in the Z direction is 310 μm. The length of the first side of the lower surface 10A is 650 μm. The length of the third side of the lower surface 10A is 250 μm. The distance from the upper end to the lower end of the primary surface 10B is 380 μm. The distance from the primary surface 10B to the fourth lateral surface 10F is 230 μm.

### Silicon Optical Member 1 of Second Example

Another example of the silicon optical member 1 manufactured based on the above-described manufacturing method will be described. FIG. 4C is an image illustrating a silicon optical member 1N2 according to the second example. In the silicon optical member 1N2, the width between a side of the first lateral surface 10C meeting the lower surface 10A and a side of the first lateral surface 10C meeting the primary surface 10B is 50 μm. The width between a side of the second lateral surface 10D meeting the third lateral surface 10E and a side of the second lateral surface 10D meeting the primary surface 10B is 50 μm. The width between aside of the fourth lateral surface 10F meeting the lower surface 10A and a side of the fourth lateral surface 10F meeting the third lateral surface 10E is 20 μm. The distance d is 40 μm. The width of the silicon member 10 in the X direction is 220 μm. The width of the silicon member 10 in the Y direction is 650 μm. The width of the silicon member 10 in the Z direction is 220 μm. The length of the first side of the lower surface 10A is 650 μm. The length of the third side of the lower surface 10A is 160 μm. The distance from the upper end to the lower end of the primary surface 10B is 250 μm. The distance from the primary surface 10B to the fourth lateral surface 10F is 170 μm.

### Silicon Optical Member 99 of Comparative Example

An example of a conventional silicon optical member 99 as a comparative example will be described. In FIG. 4A, the silicon optical member 99 of the comparative example is illustrated together with the silicon optical member 1N1 according to the first example and the silicon optical member 1N2 according to the second example. In the silicon optical member 99, the width between a side of the first lateral surface 10C meeting the lower surface 10A and a side of the first lateral surface 10C meeting the primary surface 10B is 145 μm. The width between a side of the second lateral surface 10D meeting the third lateral surface 10E and a side of the second lateral surface 10D meeting the primary surface 10B is 145 μm. The width between a side of the fourth lateral surface 10F meeting the lower surface 10A and a side of the fourth lateral surface 10F meeting the third lateral surface 10E is 250 μm. The distance d is 100 μm. The width of the silicon member 10 in the X direction is 950 μm. The width of the silicon member 10 in the Y direction is 1000 μm. The width of the silicon member 10 in the Z direction is 950 μm. The length of the first side of the lower surface 10A is 1000 μm. The length of the third side of the lower surface 10A is 650 μm. The distance from the upper end to the lower end of the primary surface 10B is 950 μm. The distance from the primary surface 10B to the fourth lateral surface 10F is 600 μm.

As described above, the silicon optical member 1 according to the embodiment is made smaller than the silicon optical member 99 of the comparative example manufactured by the conventional technique. The manufacturing process of the silicon member 99 of the comparative example does not include at least the step of forming the third primary surface on the silicon substrate described above, and the second primary surface is used as a reflective surface.

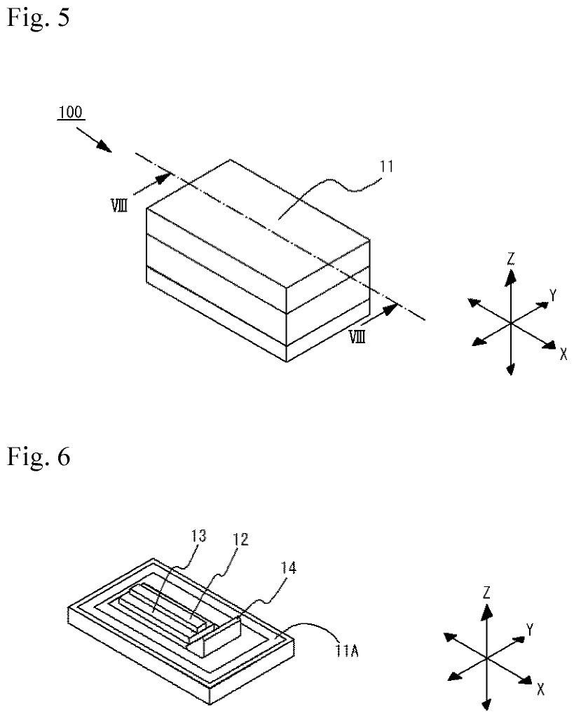

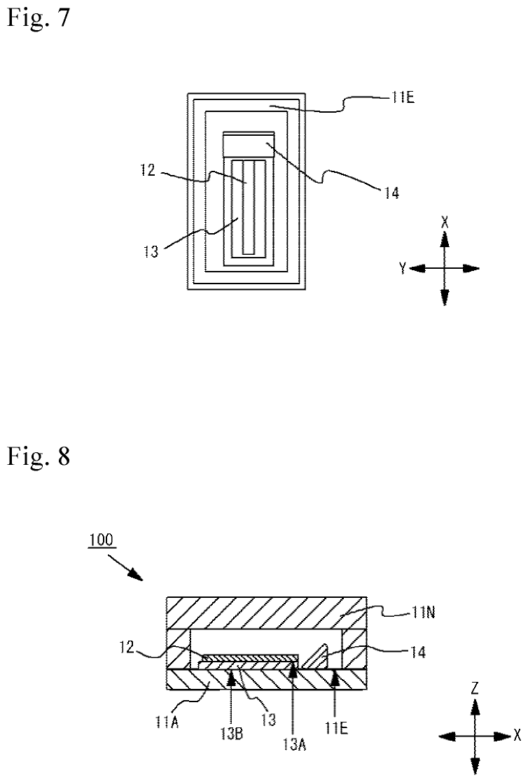

Subsequently, an example of a light-emitting device 100 including the above-described silicon optical member 1 will be described. FIGS. 5 to 8 are drawings for illustrating an exemplary form of the light-emitting device 100. FIG. 5 is a schematic perspective view of the light-emitting device 100. FIG. 6 is a schematic perspective view of the light-emitting device 100, in a state in which a cover 11N is removed. FIG. 7 is a schematic top view of the light-emitting device 100, in a state in which the cover 11N is removed. FIG. 8 is a schematic cross-sectional view taken along a section line VIII-VIII in FIG. 5.

The light-emitting device 100 includes a plurality of components. The plurality of components included in the light-emitting device 100 include a package 11, the semiconductor laser element 12, an adjustment member 13, and a reflective member 14. The light-emitting device 100 may include a component other than the components described above.

### Package 11

The package 11 includes a substrate 11A and the cover 11N. The cover 11N is bonded to the substrate 11A. The substrate 11A is formed in a plate-like shape. The substrate 11A includes a mounting surface 11E. The substrate 11A has a width (thickness) in a direction perpendicular to the mounting surface 11E in a range of 0.2 mm to 0.5 mm.

In a top view, an outer edge shape of the package 11 is rectangular. This rectangular shape can be a shape with long sides and short sides. In the package 11 illustrated in the drawings, the long side direction of the rectangle is the same direction as the X direction, and the short side direction thereof is the same direction as the Y direction. The outer edge shape of the package 11 in the top view need not be rectangular. A width of the package 11 in a direction perpendicular to the mounting surface 11E is in a range of 1 mm to 3.5 mm.

An internal space in which other components are disposed is formed in the package 11. This internal space can be a sealed space that is sealed in a vacuum or airtight state.

The substrate 11A can be formed using ceramic as a main material. Examples of the ceramic include aluminum nitride, silicon nitride, aluminum oxide, and silicon carbide.

The cover 11N includes a frame portion and an upper portion that covers a frame formed by the frame portion. The frame portion of the cover 11N is bonded to the substrate 11A.

The cover 11N is light-transmissive. The term “light-transmissive” as used herein means having light-transmittance of 80% or more. The term “light-transmissive” does not necessarily indicate having transmittance of equal to or more than 80% with respect to all wavelengths. The cover 11N may partially include a non-transmissive region (a region that is not light-transmissive).

The cover 11N is formed using glass as a main material. The main material of the cover 11N is a material having high transmittance. The cover 11N is not limited to glass and may be formed using sapphire as the main material, for example.

Semiconductor Laser Element 12 The semiconductor laser element 12 has a light-emitting surface from which light is emitted. The semiconductor laser element 12 has an upper surface, a lower surface, and a plurality of lateral surfaces. A lateral surface of the semiconductor laser element 12 serves as the light-emitting surface. The semiconductor laser element 12 has one or more the light-emitting surfaces.

A shape of the upper surface of the semiconductor laser element 12 is a rectangle with long sides and short sides. The shape of the upper surface of the semiconductor laser element 12 need not be rectangular.

As the semiconductor laser element 12, for example, a semiconductor laser element that emits blue light, a semiconductor laser element that emits green light, or a semiconductor laser element that emits red light, can be employed. A semiconductor laser element that emits light of another color can be employed as the semiconductor laser element 12.

As used herein, blue light refers to light having a light emission peak wavelength within a range of 420 nm to 494 nm. Green light refers to light having a light emission peak wavelength within a range of 495 nm to 570 nm. Red light refers to light having a light emission peak wavelength within a range of 605 nm to 750 nm.

Light (laser light) emitted from the semiconductor laser element 12 has divergence. Light emitted from an emission end surface (light-emitting surfaces) of the semiconductor laser element 12 is diverging light.

The light emitted from the semiconductor laser element 12 exhibits a far field pattern (hereinafter referred to as an “FFP”) of an elliptical shape in a plane parallel to the emission end surface of the light. The FFP indicates a shape and a light intensity distribution of the emitted light at a position away from the emission end surface.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity of 1/e² or more with respect to a peak intensity value is referred to as a main portion of the light.

The shape of the FFP of the light emitted from the semiconductor laser element 12 is an elliptical shape that is longer in a layering direction than in a direction perpendicular to the layering direction in the plane parallel to the emission end surface of the light. The layering direction is a direction in which a plurality of semiconductor layers including an active layer are layered in the semiconductor laser element 12. The direction perpendicular to the layering direction can also be referred to as a plane direction of the semiconductor layer. Furthermore, a long diameter direction of the elliptical shape of the FFP can also be referred to as a fast axis direction of the semiconductor laser element 12, and a short diameter direction can also be referred to as a slow axis direction of the semiconductor laser element 12.

Based on the light intensity distribution of the FFP, an angle at which light having a light intensity of 1/e² of a peak light intensity diverges is referred to as a divergence angle of light of the semiconductor laser element 12. For example, a divergence angle of light may also be determined based on the light intensity that is half of the peak light intensity, other than being determined based on the light intensity of 1/e² of the peak light intensity. In the description herein, the term “divergence angle of light” refers to a divergence angle of light at the light intensity of 1/e² of the peak light intensity. A divergence angle in the fast axis direction is greater than a divergence angle in the slow axis direction.

The semiconductor laser element 12 can be a semiconductor laser element including an active layer made of a GaN-based material. The semiconductor laser element 12 can be a semiconductor laser element including an active layer made of a GaAs-based material.

Examples of the semiconductor laser element 12 configured to emit blue light or the semiconductor laser element 12 configured to emit green light include a semiconductor laser element including an active layer made of a GaN-based material. Examples of the GaN-based material include GaN, InGaN, and AlGaN. Examples of the semiconductor laser element 12 configured to emit red light include a semiconductor laser element including an active layer made of a semiconductor of a GaP-based or GaAs-based material. Examples of the GaAs-based material include GaAs and AlGaAs. Examples of the GaP-based material include GaP, AlGaP, and AlGaInP. The active layer may be constituted by a semiconductor including As and P such as GaAsP.

### Adjustment Member 13

The adjustment member 13 has a first surface 13A and a second surface 13B. The second surface 13B is a surface opposite to the first surface 13A. The adjustment member 13 has a thickness (width between the first surface 13A and the second surface 13B) in a range of 50 μm to 150 μm. The adjustment member 13 is formed in a plate-like shape. In a top view, an outer shape of the adjustment member 13 is a rectangular shape with long sides and short sides. The outer shape of the adjustment member 13 in a top view need not be rectangular.

The adjustment member 13 can be formed by using metal as a main material. For example, Cu can be used for the metal as the main material. Other than Cu, Mo can be used as the main material. The adjustment member 13 maybe formed using a material other than metal as the main material.

### Reflective Member 14

The above-described silicon optical member 1 can be used for the reflective member 14. The primary surface 10B on which the reflective film 30 is provided can be used as a light reflective surface of the reflective member 14. As the reflective member 14, the primary surface 10B can also be used as the light reflective surface in a state in which the reflective film 30 is not disposed on the primary surface 10B.

In the light reflective surface of the reflective member 14, a reflectance to the peak wavelength of the light irradiated on the light reflective surface is equal to or more than 90%. The reflectance may be equal to or more than 95%. The reflectance can be equal to or more than 99%. The light reflectance is equal to or less than 100% or is less than 100%.

### Light-Emitting Device 100

In the light-emitting device 100, the semiconductor laser element 12 is disposed on the mounting surface 11E of the package 11. The semiconductor laser element 12 is configured to emit light laterally traveling from the light-emitting surface. The light emitted from the semiconductor laser element 12 is light in which a direction perpendicular to the mounting surface 11E is a fast axis direction.

The semiconductor laser element 12 is disposed on the mounting surface 11E through the adjustment member 13. The semiconductor laser element 12 is bonded to the first surface 13A of the adjustment member 13. The second surface 13B of the adjustment member 13 is bonded to the mounting surface 11E.

In the light-emitting device 100, the reflective member 14 is disposed. The reflective member 14 is configured to reflect light emitted from the semiconductor laser element 12. The light-emitting surface of the semiconductor laser element 12 faces the primary surface 10B of the reflective member 14. The reflective member 14 is disposed on the mounting surface 11E. The reflective member 14 is bonded to the mounting surface 11E.

The primary surface 10B has a width in the slow axis direction of light emitted from the semiconductor laser element 12 that is greater than a width thereof in the fast axis direction of light emitted from the semiconductor laser element 12. The primary surface 10B of the reflective member 14 has a size relationship reversed to that of the shape of the FFP of light emitted from the semiconductor laser element 12. Thus, with the reflective member 14 longer in the Y direction, the reflective member 14 can easily be mounted on the substrate 11A.

The primary surface 10B preferably has a width in the slow axis direction of light emitted from the semiconductor laser element 12 greater than the width in the fast axis direction of light emitted from the semiconductor laser element 12 by a range of 1.5 times to 6 times. With the width in the slow axis direction being 1.5 times or more the width in the fast axis direction, even when a crack or the like occurs in the fifth lateral surface 10M or the sixth lateral surface 10N in the manufacturing process of the reflective member 14, the influence of the crack on the region irradiated with light can be reduced. If the width is greater than 6 times, the size of the light-emitting device 100 may be excessively increased.

The light-emitting point on the light-emitting surface of the semiconductor laser element 12 is located closer to a lower end than to an upper end of the light-emitting surface. With the adjustment member 13 disposed therebetween, even when the light-emitting point is close to the lower end, the light reflective surface can be irradiated with all of the light of the main portion.

The adjustment member 13 has a thickness in a direction perpendicular to the mounting surface 11E in a range of 50 μm to 150 μm. The shortest distance from the semiconductor laser element 12 to the reflective member 14 in a direction parallel to the mounting surface 11E is more than 1 μm and equal to or less than 150 μm. By achieving the small silicon optical member 1, the semiconductor laser element 12 and the reflective member 14 can be close to each other to achieve the small light-emitting device 100.

A distance from the mounting surface 11E to the light-emitting point of the semiconductor laser element 12 is more than 50 μm and equal to or less than 150 μm. This distance is equal to or less than half of a distance from the mounting surface 11E to the upper end of the primary surface 10B of the reflective member 14.

The lower surface 10A of the reflective member 14 and the mounting surface 11E face each other. The lower surface 10A of the reflective member 14 is bonded to the mounting surface 11E. The metal film 20 provided on the lower surface 10A of the reflective member 14 is used for the bonding to the mounting surface 11E.

In the manufacturing process of the optical member, the metal film 1C is formed on both the first inclined surface 1A31 and the second inclined surface 1A32 of the silicon substrate 1A. Even in a state in which the silicon substrate 1A is divided to be singulated into the plurality of silicon optical members 1, the metal film 1C is formed on both the first inclined surface 1A31 and the second inclined surface 1A32. Therefore, either the first inclined surface 1A31 or the second inclined surface 1A32 may be employed as the lower surface 10A of the silicon optical member 1. The silicon optical member 1 mayhave a configuration in which the first inclined surface 1A31 serves as the lower surface 10A and the second inclined surface 1A32 serves as the third lateral surface 10E, or may have a configuration in which the first inclined surface 1A31 serves as the third lateral surface 10E and the second inclined surface 1A32 serves as the lower surface 10A.

Thus, in the silicon optical member 1 in which the metal film 20 is formed on both the lower surface 10A and the third lateral surface 10E of the silicon optical member 1, either the first inclined surface 1A31 or the second inclined surface 1A32 may be used as the lower surface 10A when the silicon optical member 1 is mounted to the light-emitting device 100. Therefore, in mounting the silicon optical member 1, it is not necessary to determine which silicon optical member 1 has the first inclined surface 1A31 or which silicon optical member 1 has the second inclined surface 1A32, which can facilitate the manufacture and improve production efficiency.

Although each of the embodiments according to the present invention has been described above, the light-emitting device according to the present invention is not strictly limited to the light-emitting device in each of the embodiments. In other words, the present invention can be achieved without being limited to the outer shape or structure of the light-emitting device disclosed by each of the embodiments. The present invention can be applied without requiring all the components being sufficiently provided. For example, in a case in which some of the components of the light-emitting device disclosed by the embodiments are not stated in the claims, the degree of freedom in design by those skilled in the art such as substitutions, omissions, shape deformations, and material changes for those components is allowed, and then the invention stated in the claims being applied to those components is specified.

The light-emitting device according to each of the embodiments can be used for a projector, a head-mounted display, lighting, an in-vehicle headlight, a display, and the like.

What is claimed is:

1. A method of manufacturing a silicon optical member, comprising:
providing a silicon substrate having a first primary surface and a second primary surface opposite to the first primary surface;
forming a mask pattern on the first primary surface;
forming one or more inclined surfaces by wet etching the silicon substrate from the first primary surface using the mask pattern as a mask;
forming a third primary surface at a location closer to the first primary surface than to the second primary surface by partially removing the silicon substrate from the second primary surface toward the first primary surface without reaching the one or more inclined surfaces while the silicon substrate is supported at the first primary surface; and
singulating the silicon substrate into a plurality of silicon optical members such that each of the plurality of silicon optical members includes the third primary surface and at least one of the one or more inclined surfaces.

2. The method of manufacturing a silicon optical member according to claim 1, wherein
the forming of the third primary surface includes forming the third primary surface such that a shortest distance from the third primary surface to the one or more inclined surfaces is in a range of 10 μm to 50 μm.

3. The method of manufacturing a silicon optical member according to claim 1, wherein
the forming of the third primary surface includes forming the third primary surface such that, when a shortest distance from a corresponding one of the one or more inclined surfaces to the third primary surface is divided into a directional component perpendicular to the corresponding one of the one or more inclined surfaces and a directional component parallel to the corresponding one of the one or more inclined surfaces, a distance of the directional component perpendicular to the corresponding one of the one or more inclined surfaces is in a range of 10 μm to 50 μm.

4. The method of manufacturing a silicon optical member according to claim 2, wherein
the forming of the one or more inclined surfaces incudes forming the one or more inclined surfaces such that a width, in a direction perpendicular to the first primary surface, of the one or more inclined surfaces is in a range of 100 μm to 300 μm.

5. The method of manufacturing a silicon optical member according to claim 1, further comprising
disposing a reflective film on the third primary surface.

6. The method of manufacturing a silicon optical member according to claim 5, wherein
the forming of the third primary surface includes forming the third primary surface such that a distance from the first primary surface to the third primary surface is in a range of 100 μm to 400 μm.

7. The method of manufacturing a silicon optical member according to claim 1, wherein
the forming of the one or more inclined surfaces includes forming a plurality of grooves each defining two inclined surfaces, facing each other, of the one or more inclined surfaces such that an interval between portions of the first primary surface adjacent to each other across a corresponding one of the plurality of grooves is in a range of 200 μm to 500 μm.

8. The method of manufacturing a silicon optical member according to claim 1, wherein
the forming of the third primary surface includes partially removing the silicon substrate from the second primary surface such that, with respect to a direction perpendicular to the first primary surface, a width of a removed portion of the silicon substrate is greater than a width of the one or more inclined surfaces.

9. A silicon optical member comprising:
a silicon member including
a lower surface,
a first lateral surface meeting the lower surface and extending upward from the lower surface,
a primary surface meeting the first lateral surface and extending obliquely upward from the first lateral surface at an angle of 45 degrees relative to the lower surface,
a second lateral surface meeting the primary surface at a position opposite to the first lateral surface and extending downward from the primary surface, and
a third lateral surface meeting the second lateral surface and extending downward from the second lateral surface at an angle of 90 degrees relative to the lower surface, wherein
a width between a side of the first lateral surface meeting the lower surface and a side of the first lateral surface meeting the primary surface is in a range of 30 μm to 100 μm, and
a width between a lower end of the primary surface and an upper end of the primary surface is greater than a width between an end point of the lower surface at a first lateral surface side and an end point of the lower surface at a third lateral surface side.

10. The silicon optical member according to claim 9, wherein
a height from the lower surface to the upper end of the primary surface is in a range of 100 μm to 550 μm.

11. The silicon optical member according to claim 9, wherein
a width between a side of the first lateral surface meeting the lower surface and a side of the first lateral surface meeting the primary surface is less than 60 μm.

12. The silicon optical member according to claim 9, further comprising
a reflective film disposed on the primary surface.

13. A light-emitting device comprising:
the silicon optical member according to claim 9;
a substrate including a mounting surface to which the silicon optical member is bonded;
an adjustment member having a first surface and a second surface opposite to the first surface, the second surface being bonded to the mounting surface, the adjustment member having a thickness in a range of 50 μm to 150 μm in a direction perpendicular to the mounting surface; and
a semiconductor laser element bonded to the first surface of the adjustment member with a light-emitting surface facing the primary surface of the silicon member of the silicon optical member, wherein
a shortest distance from the semiconductor laser element to the silicon optical member in a direction parallel to the mounting surface is more than 0 μm and equal to or less than 100 μm.

14. The light-emitting device according to claim 13, wherein
in the silicon optical member, a height from the lower surface of the silicon member to the upper end of the primary surface of the silicon member is in a range of 100 μm to 550 μm.

15. The light emitting device according to claim 13, wherein
in the silicon optical member, a width between a side of the first lateral surface of the silicon member meeting the lower surface of the silicon member and a side of the first lateral surface of the silicon member meeting the primary surface of the silicon member is less than 60 μm.

16. The light emitting device according to claim 13, wherein
the silicon optical member includes a reflective film disposed on the primary surface of the silicon member.
